(19) United States
(12) Patent Application Publication
(10) Pub. No.: US 2023/0247894 A1
(43) Pub. Date: Aug. 3, 2023

(54) MICRO THIN-FILM DEVICE

(71) Applicant: VueReal Inc., Waterloo (CA)

(72) Inventor: Gholamreza CHAJI, Waterloo (CA)

(73) Assignee: VueReal Inc., Waterloo, ON (CA)

(21) Appl. No.: 17/918,931

(22) PCT Filed: Apr. 16, 2021
(86) PCT No.: PCT/CA2021/050518

§ 371 Date: Oct. 14, 2022

Related U.S. Application Data
(60) Provisional application No. 63/011,049, filed on Apr. 16, 2020.
(60) Provisional application No. 63/015,179, filed on Apr. 24, 2020.

(51) Int. Cl. H10K 71/80; H10K 50/805; H10K 50/844; H10K 50/88; H10K 59/90

(52) U.S. Cl. CPC H10K 71/80; H10K 50/805; H10K 50/844; H10K 50/88; H10K 59/90; H10K 50/10

(57) ABSTRACT

This invention discloses methods to form a micro thin film device. The methods use release layer on a substrate, encapsulation layers, electrode formation, and forming a bank layer. The methods further use VIA's to provide access to pads. The methods also entail transfer of multiple micro thin film devices by forming micro thin film devices on a cartridge, forming a housing, using anchors, and covering a side wall of the housing with a release layer.

### BACKGROUND AND FIELD OF THE INVENTION

The present invention relates to formation of micro thin film devices.

### SUMMARY

The invention relates to an embodiment describing method to form a micro thin film device comprising, having a release layer on a substrate, forming a encapsulation layer on the release layer or the substrate, forming a first electrode on the encapsulation layer, and forming a bank layer on the first electrode to define a micro thin film area.

Another embodiment relates to a method to form a micro thin film device comprising, having a release layer on a substrate, forming pads on the release layer or the substrate, forming an encapsulation layer on the release layer or the substrate, forming a VIA to provide access to the pads, forming a first electrode on the encapsulation layer, and forming a bank layer on the first electrode to define a micro thin film area.

Another embodiment relates to a method to transfer multiple micro thin film devices comprising, forming micro thin film devices on a cartridge, forming a housing for each thin film device, holding the device with an anchor, covering a side wall of the housing with a release layer, and transferring micro thin film devices to a system backplane.

### BRIEF DESCRIPTION OF THE DRAWINGS

The foregoing and other advantages of the disclosure will become apparent upon reading the following detailed description and upon reference to the drawings.

FIG. 1. shows a micro thin film device, formed on a substrate.

FIG. 2. shows VIA's formed to provide access to electrode layers.

FIG. 2A. shows Pillar/Staging structure can form underneath the pads.

FIG. 3. shows a second electrode is formed on top of the micro thin film layers.

FIGS. 4 and 5. show pads coupling to the first and second electrode at two different side of the micro thin film layers.

FIG. 6. shows a housing formed around the device.

FIGS. 7-10. show micro thin film devices being transferred into the system substrate by different means.

FIGS. 11 and 12 show a planarization layer.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of the invention as defined by the appended claims.

### DETAILED DESCRIPTION

In this description, the terms “micro thin film device” and “micro device” and “device” are used interchangeably. However, it is clear to one skilled in the art that the embodiments described here are independent of the device size.

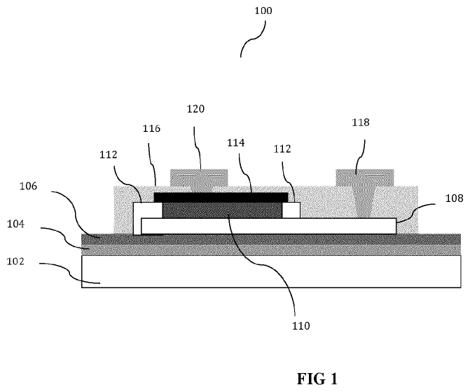

As shown in FIG. 1, a micro thin film device 100, can be formed on a substrate 102. There can be a release layer 104 on the substrate. A passivation/encapsulation and/or mechanical foundation layer 106 is formed on the release layer 104 or the substrate 102.

A first electrode 108 is formed on the encapsulation layer 106. Bank layer 112 can be formed on or around the first electrode 108 to define the micro thin film area. The micro thin film layers 110 are deposited and patterned. The patterning is done by one of shadow mask, laser ablation, printing, or lithography and the deposition is done by one of a thermal, an e-beam, a sputtering, or a printing, or other chemical or physical assisted deposition. A second electrode 114 is formed on top of the micro thin film layers 110. A second passivation/encapsulation layer or mechanical foundation layer 116 is developed covering all the layers underneath. In one case the mechanical foundation can be formed on the substrate or the release layer or the second encapsulation layer. in another case the mechanical foundation is part of the first or second encapsulation layer.

A VIA is formed to provide access to the first 108 and second 114 electrode layers. Pad 118 and 120 are formed to bring the access to the first 108 and second 114 conductive layers to the top of the second encapsulation layer 116.

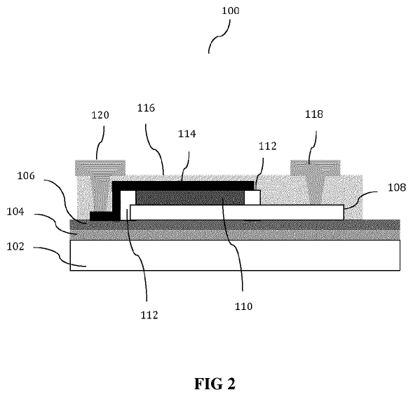

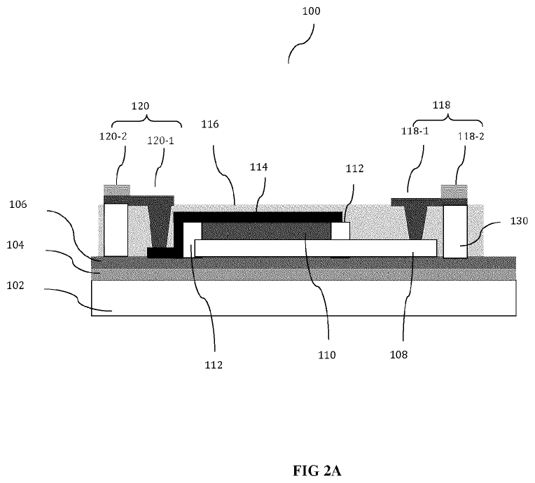

In another embodiment as shown in FIG. 2, to prevent any damage to the micro thin film layers 110 during VIA opening and/or transferring the micro thin film device 100 to a system substrate, the second electrode 114 is extended beyond the bank layer 112. The VIA is open to the second electrode 112 on the extended area. In another case, the second encapsulation layer can end and leave part of the second electrode 114 exposed for coupling a pad or other layer to it.

In another embodiment as shown in FIG. 2A, a pillar/staging structure 130 can be formed underneath the pads 120 or 118. This structure can be also around the thin film layer, protecting the layers from damage during transfer to another substrate. The pads 120 and 118 can have two parts, one part 118-1, 120-1 for coupling to the electrodes 114 and 108. The second part 118-2, 120-2 is formed for bonding/coupling to the backplane after the micro thin film device is transferred to the system substrate. The first part can be covered by a dielectric layer.

In another embodiment as shown in FIG. 3, a micro thin film device 100, formed on a substrate 102. There can be a release layer 104 on the substrate. Pads 118 and 120 are formed on the release layer (or on the substrate). A passivation/encapsulation and/or mechanical foundation layer 106 is formed and VIA can be formed to provide access to the pads 118 and 120. A first electrode layer 108 is formed on encapsulation layer 106. The first electrode can be deposited to couple with both pads 118 and 120 or only 118.

Bank layer 112 can be formed on or around the first electrode 108 to define the micro thin film area. The micro thin film layers 110 are deposited and patterned. The pattering can be done either by shadow mask, laser ablation, printing, or other forms. Here, a via to the pads 120 can form if it is not formed already. A second electrode 114 is formed on top of the micro thin film layers 110 and extended over the bank layer 112 to couple with the pad 120. A second encapsulation layer or mechanical foundation layer 116 is developed covering all the layers underneath.

Similar staging structure as previous structure as shown in FIG. 2A can be formed for the pads 118 and 120 here as well.

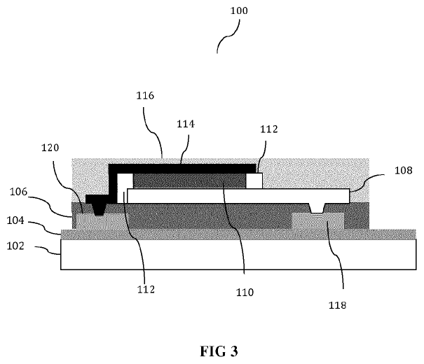

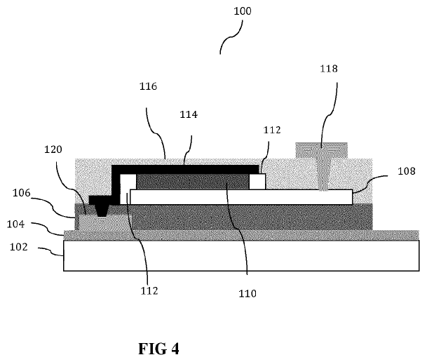

FIGS. 4 and 5 show a combination of the previous embodiments as given by FIGS. 1, 2 and 3 that can be used to provide pads coupling to the first and second electrode at two different sides of the micro thin film layers 110.

In one case, the bank layer is a dielectric layer. It can be polymer, SiN or SiO2, ALD or other types of dielectric materials.

In another case, encapsulation or mechanical foundation layers can be multi layers. In one case, the encapsulation can be achieved by organic-inorganic layers as a thick organic layer used as a foundation. The inorganic layer(s) can be formed by using either PECVD or ALD or sputtering or other deposition methods. In another case, a thick inorganic layer can be used as a mechanical foundation layer. The mechanical foundation can be part of encapsulation structure. The mechanical foundation layer provides mechanical stability to the device for transfer and prevents the layers from cracking.

In the aforementioned method, there can be more than one bank structure formed on the first electrode 108 and inside each bank structure a different micro thin film device is formed. In one case, the devices can be red, green, blue organic light emitting diodes. Here, the first or second electrode can be shared or patterned to provide individual control for each micro device.

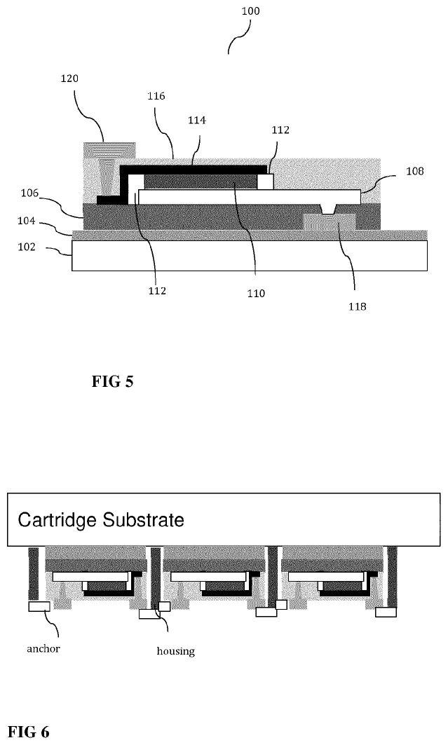

In another embodiment, as shown in FIG. 6, multiple micro thin film devices can be formed on the cartridge. In another case, there can be different type of micro devices on the same cartridge so that when they are transferred into the system backplane, different types of micro devices are transferred at the same time.

In one case, micro thin film devices can be micro organic light emitting devices (Micro-OLED).

There can be housing formed around the device as shown in FIG. 6. This housing can be part of the device development. Housing can also be formed after the device is developed.

In another case, the housing is formed, and the micro thin film device is developed inside of the housing.

The housing can be polymer or inorganic dielectric layers.

As shown in FIG. 6, an anchor can hold the device to the housing or to the cartridge substrate. The release layer can be also covering the side wall of the housing as well.

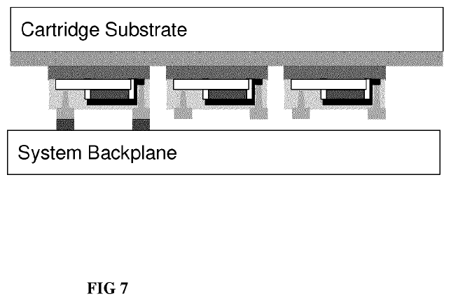

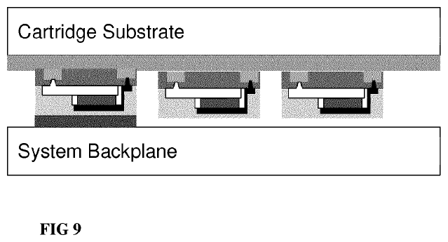

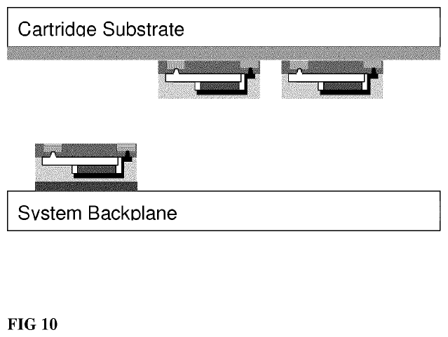

The micro thin film device can be transferred into the system substrate by different means as shown in FIGS. 7, 8, 9 and 10.

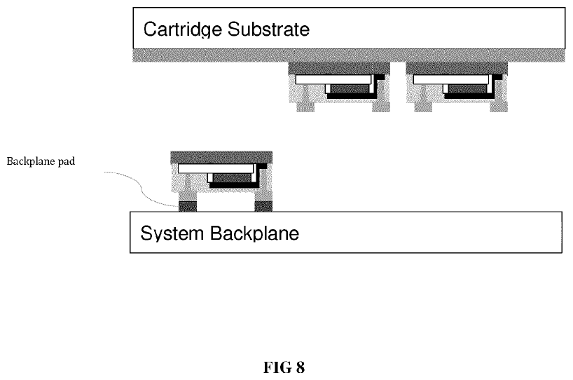

In one case, as shown in FIGS. 7 and 8, a micro thin film device is transferred directly from the cartridge into the system substrate. The micro-TF device is bonded to the backplane and it is separated from the cartridge substrate through the release layer. Here the release can be thermal, optical, or chemical or mechanical. The release can be part of the transfer or happens prior to the transfer or after the bonding. In addition, the bond can be electrical or mechanical (adhesive).

Other micro devices can be also integrated into the system backplane to form pixels. After the integration, post processing can be performed. The post processing can be encapsulation, planarization, or electrode deposition.

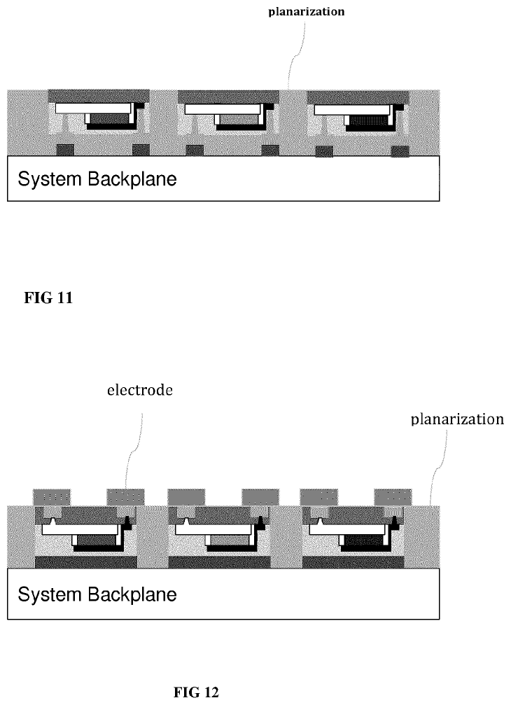

Planarization layers as shown in FIGS. 11 and 12 can be polymer or other dielectric devices. The planarization layer can be black matrix.

### Method Aspects

This invention discloses a method to form a micro thin film device. The method comprises multiple aspects including, one, having a release layer on the substrate. Two, forming an encapsulation layer on the release layer or the substrate. Three, forming a first electrode on the encapsulation layer. Four, forming a bank layer on the first electrode to define a micro thin film area. Further, wherein the layers of the micro thin film area being deposited and patterned, the patterning is done by one of either shadow mask, laser ablation, printing, or lithography. The deposition is done by one of either a(n) thermal, e-beam, sputtering, printing, or other chemical or physical assisted deposition. Next, a second electrode is formed on the layers of the micro thin film area, and a second encapsulation layer is developed covering all the layers underneath. Here, a VIA is formed to provide access to the first and second electrode, and pads are formed to bring the access to the first and second electrodes to the top of the second encapsulation layer. Further, the second electrode is extended beyond the bank layer and the VIA is open to the second electrode. The second encapsulation layer ends and leaves part of the second electrode exposed for coupling a pad or other layer to it. Additionally, the micro thin film device has a mechanical foundation that is formed on the substrate or the release layer or the second encapsulation layer. The mechanical foundation is also part of the first or second encapsulation. Further, a pillar structure is formed underneath the pads formed to bring access to the first and second electrodes to the top of the second encapsulation layer. The pads have two parts, one for coupling to the electrodes and the second to bond to the backplane after the micro thin film device is transferred to the substrate. Here, the first part of the pads is covered by a dielectric layer.

This invention discloses a method to form a micro thin film device. The method comprises multiple aspects including, one, having a release layer on a substrate. Two, forming pads on the release layer or the substrate. Three, forming an encapsulation layer on the release layer of the substrate. Four, forming a VIA to provide access to the pads. Five, forming a first electrode on the encapsulation layer. Six, forming a bank layer on the first electrode to define a micro thin film area. Further, the first electrode is deposited to couple with one or both the pads, and layers of the micro thin film area are deposited and patterned. Here, the patterning is done by one of either a shadow mask, laser ablation, lithography, or printing. The deposition is done by one of a(n) thermal, e-beam, sputtering, printing, or other chemical or physical assisted deposition. Next, a second electrode is formed on the layers of the micro thin film area and extended over the bank layer to couple with one pad. Further, a second encapsulation layer is developed covering all layer's underneath. The bank layer is a dielectric layer, and it is one of materials such as a(n) polymer, SiN, SiO2, ALD or other types of dielectric materials. Additionally, the encapsulation layer is more than one layer; it is an organic-inorganic layer. The organic-inorganic layer(s) are formed by one of a PECVD, an ALD, a sputtering or other deposition methods.

This invention further discloses a method to transfer multiple micro thin film devices. The method comprises multiple aspects including, one, forming micro thin film devices on a cartridge. Two, forming a housing for each thin film device. Three, holding the device with an anchor. Four, covering a side wall of the housing with a release layer. Five, transferring micro thin film devices into a system backplane. To start, the micro thin film devices are bonded to the system substrate and separated from the cartridge substrate through the release layer. Here, the release layer is one of a(n) thermal, optical, or mechanical and the bonding is electrical or mechanical (adhesive). Additionally, the micro thin film devices are of different types. Further, a post processing is performed after the transfer; and the post processing is one of an encapsulation, a planarization, or an electrode deposition. The planarization layer is a polymer or other dielectric devices, and it is a black matrix. Next, the micro thin film devices are micro organic light emitting devices (Micro-OLED). There are more than one bank structures formed on the first electrode and inside each bank structure a different micro thin film device is formed. The micro thin film devices can be red, green, blue organic light emitting diodes. Here, the first or second electrode are shared or patterned to provide individual control for each micro device. Lastly, different types of micro thin film devices are formed on the cartridge.

The foregoing description of one or more embodiments of the invention has been presented for the purposes of illustration and description. It is not intended to be exhaustive or to limit the invention to the precise form disclosed. Many modifications and variations are possible in light of the above teachings. It is intended that the scope of the invention be limited not by this detailed description, but rather by the claims appended hereto.

1. A method to form a micro thin film device the method comprising:
having a release layer on a substrate;
forming a encapsulation layer on the release layer or the substrate;
forming a first electrode on the encapsulation layer; and
forming a bank layer on the first electrode to define a micro thin film area.

2. The method of claim 1, wherein layers of the micro thin film area are deposited and patterned.

3. The method of claim 2, wherein the patterning is done by one of shadow mask, laser ablation, printing, or lithography and the deposition is done by one of a thermal, an e-beam, a sputtering, a printing, or other chemical or physical assisted deposition.

4. The method of claim 1, wherein a second electrode is formed on the layers of the micro thin film area.

5. The method of claim 4, wherein a second encapsulation layer is developed covering all layers underneath.

6. The method of claim 5, wherein a VIA is formed to provide access to the first and second electrode.

7. The method of claim 6, wherein pads are formed to bring the access to the first and second electrodes to the top of the second encapsulation layer.

8. The method of claim 6, wherein the second electrode is extended beyond the bank layer and the VIA is open to the second electrode.

9. The method of claim 6, wherein the second encapsulation layer ends and leaves part of the second electrode exposed for coupling a pad or other layer to it.

10. The micro thin film device of claim 1 wherein the device has a mechanical foundation.

11. The mechanical foundation of claim 10 where the mechanical foundation is formed on the substrate or the release layer or the second encapsulation layer.

12. The method of claim 10 where the mechanical foundation is part of the first or the second encapsulation.

13. The method of claim 7, wherein a pillar structure is formed underneath the pads.

14. The method of claim 13, wherein the pads have two parts, one for coupling to the electrodes and the second to bond to the backplane after the micro thin film device is transferred to the substrate.

15. The method of claim 14, wherein the first part of the pads is covered by a dielectric layer.

16. A method to form a micro thin film device the method comprising:
having a release layer on a substrate;
forming pads on the release layer or the substrate;
forming an encapsulation layer on the release layer or the substrate;
forming a VIA to provide access to the pads;
forming a first electrode on the encapsulation layer; and
forming a bank layer on the first electrode to define a micro thin film area.

17. The method of claim 16, wherein the first electrode is deposited to couple with one or both the pads.

18. The method of claim 16, wherein layers of the micro thin film area are deposited and patterned.

19. The method of claim 18, wherein the patterning is done by one of shadow mask, laser ablation, lithography, or printing and the deposition is done by one of a thermal, an e-beam, a sputtering, a printing, or other chemical or physical assisted deposition.

20. The method of claim 16, wherein a second electrode is formed on the layers of the micro thin film area and extended over the bank layer to couple with one pad.

21. The method of claim 20, wherein a second encapsulation layer is developed covering all layers underneath.

22. The method of claim 1, wherein the bank layer is a dielectric layer, and the bank layer is one of materials such as a polymer, a SiN, a SiO2, an ALD or other types of dielectric materials.

23. The method of claim 16, wherein the bank layer is a dielectric layer, and the bank layer is one of materials such as a polymer, a SiN, a SiO2, an ALD or other types of dielectric materials.

24. The method of claim 1, wherein the encapsulation layer is more than one layer.

25. The method of claim 24, wherein the encapsulation layer is an organic-inorganic layer.

26. The method of claim 25 wherein the in-organic layer(s) are formed by one of a PECVD, an ALD, a sputtering or other deposition methods.

27. The method of claim 16, wherein the encapsulation layer is more than one layer.

28. The method of claim 27, wherein the encapsulation layer is an organic in-organic layer.

29. The method of claim 28, wherein the in-organic layer(s) are formed by one of a PECVD, an ALD, a sputtering or other deposition methods.

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)
